(19) United States
(12) Patent Application Publication
(10) Pub. No.: US 2022/0247059 A1
(43) Pub. Date: Aug. 4, 2022

(54) Impedance Converter

(71) Applicant: Nippon Telegraph and Telephone Corporation, Tokyo (JP)

(72) Inventors: Miwa Muto, Tokyo (JP); Hideaki Matsuzaki, Tokyo (JP)

(21) Appl. No.: 17/611,820

(22) PCT Filed: May 22, 2019
(86) PCT No.: PCT/JP2019/020251

§ 371 Date: Nov. 16, 2021

(51) Int. Cl. H01P 3/08; H05K 1/02

(52) U.S. Cl. CPC H01P 3/088; H05K 1/0215; H05K 1/024; H05K 1/025

(57) ABSTRACT

An impedance converter includes a dielectric substrate, a ground layer formed on a rear surface of the dielectric substrate, and a signal line formed in a layer from an inside to a front surface of the dielectric substrate with a distance to the ground layer gradually changed along a signal transfer direction. The signal line includes a plurality of lines stacked in the layer from the inside to the front surface of the dielectric substrate with the distance to the ground layer gradually changed along the signal transfer direction.

This patent application is a national phase filing under section 371 of PCT/JP2019/020251, filed on May 22, 2019, which is incorporated herein by reference in its entirety.

### TECHNICAL FIELD

The present invention relates to an impedance converter for a semiconductor high-frequency module.

### BACKGROUND

A microstrip line is used as a transmission line used for a high-frequency circuit. In the microstrip line, a ground surface including a planar conductor layer is formed at one surface of a dielectric substrate and a belt-shaped line is formed at the other surface of the dielectric substrate, serving as a transmission line. A characteristic impedance of the microstrip line is determined depending on a width and a thickness of the strip line and a permittivity and a thickness of the dielectric substrate.

In a case where, for example, a load circuit or a signal source with a certain impedance is connected to the high-frequency circuit, it is necessary to match the characteristic impedances of the high-frequency circuit and the load circuit or the signal source to cause an electric power or a signal to be efficiently transferred through a connection portion. To achieve such impedance matching, an impedance converter configured to have different characteristic impedances at opposite ends of the microstrip line is used (see Non-Patent Literature 1).

FIG. 9A shows a plan view of a structure of a conventional impedance converter, FIG. 9B is a cross-sectional view of the impedance converter shown in FIG. 9A taken along an A-A′ line, and FIG. 9C is a cross-sectional view of the impedance converter shown in FIG. 9A taken along a B-B′ line. In the impedance converter that performs impedance conversion with a transmission line, to prevent deterioration in transmission performance due to a rapid change in impedance in a high frequency band, a width of signal lines 102 is gradually changed to convert the characteristic impedance of the microstrip line to a desired impedance as shown in FIG. 9A to FIG. 9C. FIG. 9A to FIG. 9C further illustrate a dielectric substrate 100 and a ground layer 101.

The number of signals to be inputted to/outputted from a semiconductor high-frequency module has been increased to enhance a function of a semiconductor high-frequency module these years. However, an enhancement in function and a reduction in costs of the semiconductor high-frequency module require a reduction in a contour size of the module, which results in progression of miniaturization of a substrate connection pad and a pad interval. Thus, an increase in the number of signals of the semiconductor high-frequency module and miniaturization of the substrate connection pad have progressed. As a result, in a wiring substrate that is to be connected to the semiconductor high-frequency module, it is desired to provide a transmission line that allows for routing a lot of signals at a high density and an impedance converter that performs impedance conversion with the transmission line with high frequency characteristics maintained.

In a case where the impedance conversion is performed with the transmission line with the high frequency characteristics maintained, a line width is gradually changed in a tapered shape according to a conventional technology. However, as shown in FIG. 10A, an interval di between substrate connection pads 103 has to be increased to ensure a sufficient interval between signal lines 102, which disadvantageously increases a size of the impedance converter. In addition, as shown in FIG. 10B, an interval d2 between the signal lines 102 decreases with an increase in a width of the signal lines 102, which disadvantageously increases crosstalk noise between the signal lines 102.

The crosstalk noise between the signal lines 102 is generated when a signal pulse is transmitted through one of the signal lines 102, by causing electrons in the other signal line 102 to be displaced. Thus, a smaller interval between the signal lines 102 causes a larger displacement of the electrons in the other signal line 102, which results in a larger crosstalk noise. As is understood from the above, the conventional impedance converter is unlikely to achieve both an improvement in line density and a reduction in crosstalk noise between lines and thus unlikely to be adapted to high-density mounting.

### CITATION LIST

### Non-Patent Literature

Non-Patent Literature 1: P. Pramanick, et al., “Tapered Microstrip Transmission Lines”, IEEE MTT-S Int. Microw. Symp. Dig., vol. 1983, pp. 242-244, 1983.

### SUMMARY

### Technical Problem

Embodiments of the present invention can solve the above-described problems and an embodiment thereof provides an impedance converter that can achieve both an improvement in line density and a reduction in crosstalk noise between lines.

### Means for Solving the Problem

An impedance converter according to embodiments of the present invention includes: a dielectric substrate; a ground layer formed on a rear surface of the dielectric substrate; and a signal line formed in a layer from an inside to a front surface of the dielectric substrate with a distance to the ground layer gradually changed along a signal transfer direction.

### Effects of Embodiments of the Invention

According to embodiments of the present invention, a signal line is provided in a layer from an inside to a front surface of the dielectric substrate with a distance to the ground layer gradually changed along a signal transfer direction, which allows for setting a desired characteristic impedance value and providing an impedance converter in which an input-side characteristic impedance and an output-side characteristic impedance are different from each other. In addition, embodiments of the present invention allow for reducing crosstalk noise between lines. As a result, embodiments of the present invention allow for miniaturizing an interval between signal lines (an interval between adjacent substrate connection pads) with crosstalk noise regulated to substantially the same amount as ever and providing an impedance converter adaptable to high-density mounting with both an improvement in line density and a reduction in crosstalk noise between lines achieved.

### BRIEF DESCRIPTION OF THE DRAWINGS

FIG. 1A and FIG. 1B are a plan view and a cross-sectional view of an impedance converter of embodiments of the present invention.

FIG. 2A to FIG. 2C are cross-sectional views of the impedance converter of embodiments of the present invention.

FIG. 3 shows a characteristic impedance of each of an impedance converter according to an Example of embodiments of the present invention and a conventional impedance converter.

FIG. 4 is a cross-sectional view for explaining a distance between a signal line and a ground layer and a line-to-line distance of the impedance converter according to the Example of embodiments of the present invention.

FIG. 5 shows a relationship among the characteristic impedance of the impedance converter according to the Example of embodiments of the present invention, the distance between the signal line and the ground layer, and a thickness of the signal line.

FIG. 6A to FIG. 6D each show a model of a microstrip line provided by an electromagnetic field simulator.

FIG. 7 shows a simulation result of backward crosstalk of each of the impedance converter according to the Example of embodiments of the present invention and the conventional impedance converter.

FIG. 8 shows a simulation result of forward crosstalk of each of the impedance converter according to the Example of embodiments of the present invention and the conventional impedance converter.

FIG. 9A to FIG. 9C are a plan view and cross-sectional views of a structure of the conventional impedance converter.

FIG. 10A and FIG. 10B are plan views for explaining disadvantages of the conventional impedance converter.

### DETAILED DESCRIPTION OF ILLUSTRATIVE EMBODIMENTS

### Principle of Embodiments of the Invention

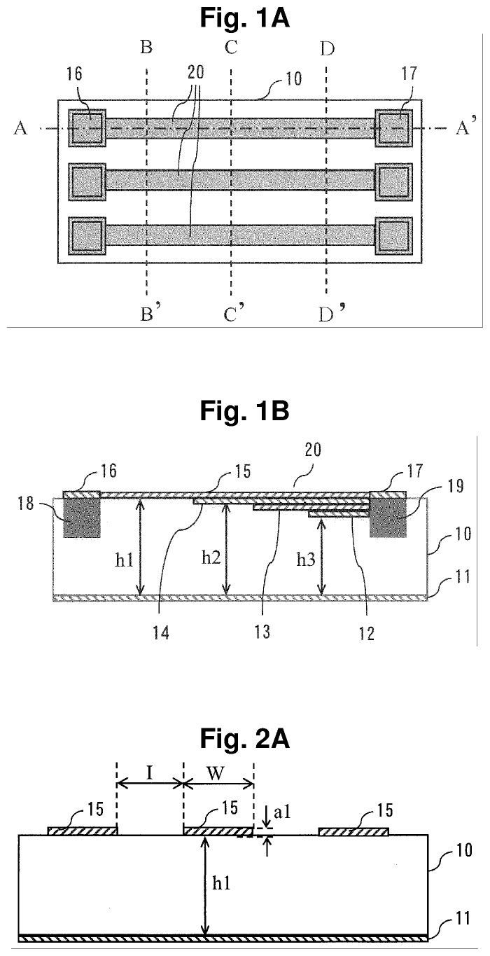

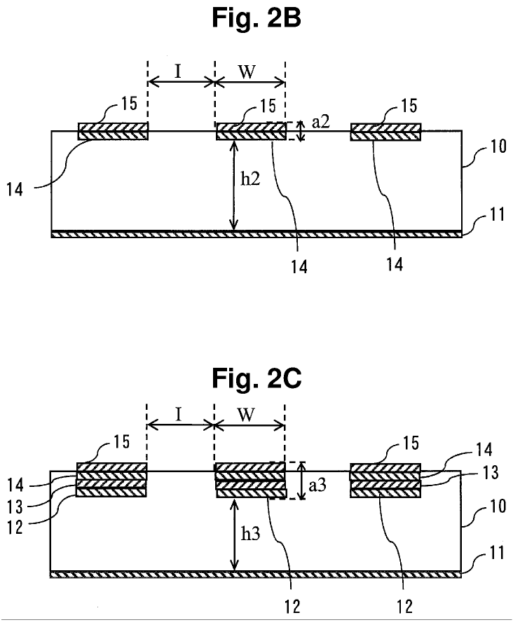

FIG. 1A is a plan view of an impedance converter of embodiments of the present invention and FIG. 1B is a cross-sectional view of the impedance converter shown in FIG. 1A taken along an A-A′ line. FIG. 2A is a cross-sectional view of the impedance converter shown in FIG. 1A taken along a B-B′ line, FIG. 2B is a cross-sectional view of the impedance converter shown in FIG. 1A taken along a C-C′ line, and FIG. 2C is a cross-sectional view of the impedance converter shown in FIG. 1A taken along a D-D′ line.

A microstrip line of embodiments of the present invention includes a dielectric substrate 10, a ground layer 11 formed on a rear surface of the dielectric substrate 10, a plurality of signal lines 20 each formed in a layer from an inside to a front surface of the dielectric substrate 10 with a distance to the ground layer 11 gradually changed along a signal transfer direction (a right-and-left direction in FIG. 1A and FIG. 1B), and substrate connection pads 16 and 17 formed to be connected to end portions of each of the signal lines 20 on the front surface of the dielectric substrate 10.

The signal lines 20 are spaced from each other in a direction perpendicular to the signal transfer direction. Further, the signal lines 20 each include a plurality of lines 12 to 15 stacked in the layer from the inside to the front surface of the dielectric substrate 10 with the distance to the ground layer 11 gradually changed along the signal transfer direction. The plurality of lines 12 to 15 are stacked with ends thereof on either a signal input side or a signal output side (in the Example, the output side) aligned and lengths of the lines from these ends to the other ends are different from each other.

As is understood from the above, embodiments of the present invention have a configuration in which the plurality of lines 12 to 15 are stacked in sequence with the lengths of the lines 12 to 15 changed, whereby a thickness of the signal lines 20 is gradually changed in order of a1, a2, and a3 (a1<a2<a3). In an example shown in FIG. 2A to FIG. 2C, a1 is a thickness of the line 15, a2 is a total thickness of the lines 14 and 15, and a3 is a total thickness of the lines 12 to 15.

Since the dielectric substrate 10 has a constant thickness, embodiments of the present invention have a configuration in which the distance between each of the signal lines 20 and the ground layer ii is gradually changed in order of h1, h2, and h3 (h1>h2>h3). In the example shown in FIG. 1B and FIG. 2A to FIG. 2C, h1 is a distance between the line 15 and the ground layer 11, h2 is a distance between the line 14 and the ground layer 11, and h3 is a distance between the line and the ground layer 11.

As is understood from the above, in embodiments of the present invention, the distance between each of the signal lines 20 and the ground layer 11 is gradually changed, which makes it possible to continuously change a characteristic impedance with a line width W and a line interval I unchanged.

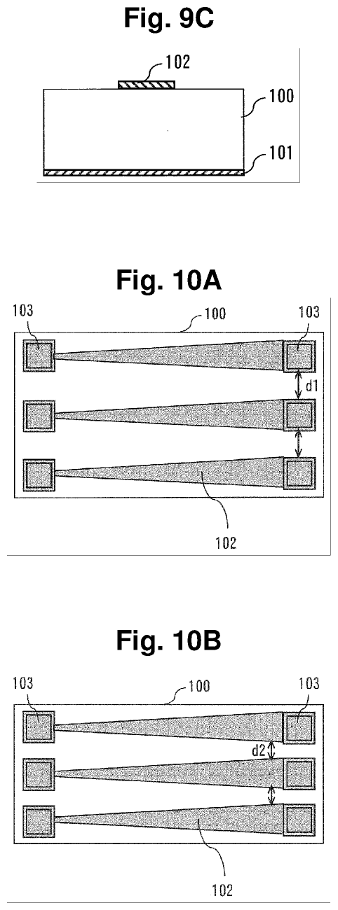

In a microstrip line, a characteristic impedance decreases with a decrease in a distance between a signal line and a ground layer. Further, the characteristic impedance decreases with an increase in a line thickness. A conventional configuration shown in FIG. 9A to FIG. 9C, FI. 10A, and FIG. 10B, which requires an increase in the line width to reduce the characteristic impedance, is unlikely to be adapted to high-density mounting for which miniaturization of a pad interval and an improvement in line density both need to be achieved. In contrast, embodiments of the present invention allow for providing an impedance converter in which a characteristic impedance of an input portion of a microstrip line is different from a characteristic impedance of an output portion without the necessity of increasing the line width W and the necessity of increasing a substantial line-to-line distance (W+I) as seen from the above.

Further, in the conventional configuration shown in FIG. 9A to FIG. 9C, FIG. 10A, and FIG. 10B, the line interval decreases with an increase in the line width. In contrast, embodiments of the present invention allow for adjusting the characteristic impedance without the necessity of changing the line width W and the line interval I, which makes it possible to reduce crosstalk noise. As is understood from the above, embodiments of the present invention can achieve an effect in reducing crosstalk noise between the lines along with an impedance conversion function without the necessity of reducing the line density.

Regarding an impedance converter, as a technology for changing a distance between a signal line and a ground layer, for example, one described in Japanese Patent Laid-Open No. 2013-251863 is known. However, an impedance converter described in Japanese Patent Laid-Open No. 2013-251863, which has a three-dimensional structure with a ground layer tilted, is unlikely to be put into practical use due to a difficulty in actually implementing a manufacturing process thereof. The impedance converter of embodiments of the present invention, which can perform impedance conversion merely by two-dimensional structure stacking, is simple in manufacturing process and can be put into practical use and reduced in costs.

Thus, according to embodiments of the present invention, it is possible to adjust the characteristic impedance of the microstrip line without the necessity of changing a width of the strip line. Therefore, embodiments of the present invention allow for forming an impedance converter that can achieve all of miniaturization of a pad interval, an improvement in line density, and a reduction in crosstalk noise between lines and that is adaptable to high-density mounting.

### Example

Next, description will be made on an Example of embodiments of the present invention. An impedance converter of the Example is a specific example of a configuration described in the Principle of Embodiments of the Invention, so that the Example will also be described with reference to FIG. 1A, FIG. 1B, and FIG. 2A to FIG. 2C.

Referring to FIG. 1A, FIG. 1B, and FIG. 2A to FIG. 2C, the plate-shaped ground layer 11 made of a conductor member such as Au is formed on one surface (rear surface) of the dielectric substrate 10 formed of benzocyclobutene (BCB) or the like. The belt-shaped signal lines 20 made of a conductor member such as Au are each formed in a layer from the inside of the dielectric substrate 10 to the other surface (front surface) thereof with the distance to the ground layer 11 gradually changed along the signal transfer direction. The signal lines 20 each include the plurality of lines 12 to 15 as described above.

The substrate connection pads 16 and 17 made of a conductor member such as Au are formed on the front surface of the dielectric substrate 10 to be electrically connected to opposite ends of each of the signal lines 20, respectively.

In the Example, since the plurality of lines 12 to 15 are stacked in sequence, as long as the substrate connection pads 16 and 17 are formed to be electrically connected to the line 15 on the front surface of the dielectric substrate 10, the substrate connection pads 16 and 17 are connected also to the lines 12 to 14. However, in the Example, vias 18 and 19 that electrically connect side surfaces of the lines 12 to 14 and lower surfaces of the substrate connection pads 16 and 17 are provided to make connection between the lines 12 to 14 and the substrate connection pads 16 and 17 more reliable. In an example of FIG. 1B, the side surfaces of the lines 12 to 14 and the lower surface of the substrate connection pad 17 are connected through the via 19. The vias 18 and 19 are not essential components for embodiments of the present invention and a structure without the vias 18 and 19 is also acceptable.

One end (input side) of the impedance converter of the Example has an input impedance Z, and the other end (output side) has an output impedance Zₒ (Zᵢ>Zₒ). In the example of FIG. 1A and FIG. 1B, a left end is the input side and a right end is the output side. With the plurality of lines 12 to 15 stacked from the inside of the dielectric substrate 10 to the front surface of the dielectric substrate 10, the distance between each of the signal lines 20 (lines 12 to 15) and the ground layer 11 is gradually reduced in order of h1, h2, and h3 (h1>h2>h3), from the input side toward the output side. The characteristic impedance is thus gradually reduced from Zᵢ to Zₒ.

A parallel plate capacitor, in which a polar-plate-to-polar-plate interval is significantly small as compared with a length of one side of each of the polar plates, is supposed to have a uniform electric field between the polar plates. In this case, a parallel capacitance C is proportional to a polar plate area S and inversely proportional to a polar-plate-to-polar-plate interval d.

$$\begin{matrix}Expression ( 1 ) & \\ C = \frac{ɛ S}{d} & ( 1 )\end{matrix}$$

ε in Expression (1) is permittivity. A reduction in a distance d between each of the signal lines and the ground layer of the microstrip line causes the parallel capacitance C to exceed a value defined by Expression (1). In addition, an electric resistance R of a conductor is inversely proportional to a cross-sectional area A [m²] of the conductor and proportional to a length L[m] and a resistivity ρ[Ωm] of the conductor.

$$\begin{matrix}Expression ( 2 ) & \\ R = \frac{ρ L}{A} & ( 2 )\end{matrix}$$

An increase in the thickness of the signal lines causes the electric resistance R of the signal lines to fall below a value defined by Expression (2). Meanwhile, the characteristic impedance Zₒ of the microstrip line is represented by Expression (3).

$$\begin{matrix}Expression ( 3 ) & \\ {Z}_{0} = \sqrt{\frac{R + j ω L}{G + j ω C}} & ( 3 )\end{matrix}$$

Here, R is a series resistance (c) of the signal lines per unit of length, L is a series inductance (H) of the signal lines per unit of length, G is a parallel conductance (S) of the signal lines per unit of length, and C is a parallel capacitance (F) of the signal lines per unit of length. Since the characteristic impedance decreases with a decrease in the distance between each of the signal lines and the ground layer and an increase in the thickness of the signal lines according to Expression (1) to Expression (3), the microstrip line according to the Example forms an impedance converter having a larger characteristic impedance on the input side and a smaller characteristic impedance on the output side.

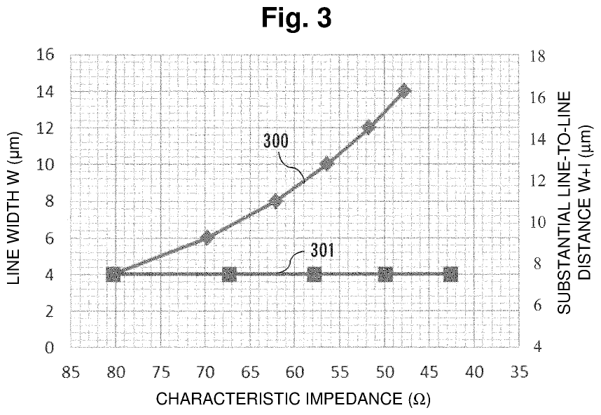

FIG. 3 shows the output-side characteristic impedance Zₒ of an impedance converter having a line length of 300 μm in which Au (gold) is used as a material of the lines 12 to 15 and the ground layer 11, a benzocyclobutene (BCB) substrate (permittivity εr=2.7) is used as the dielectric substrate 10. Reference number 300 in FIG. 3 shows the output-side characteristic impedance Zₒ of the conventional impedance converter shown in FIG. 9A to FIG. 9C, FIG. 10A, and FIG. 10B and reference number 301 shows the output-side characteristic impedance Zₒ of the impedance converter of the Example.

Here, the input-side line width of the conventional impedance converter was fixed at 4 μm and the output-side line width was W μm. The input-side width and the output-side width of the signal lines 20 of the impedance converter of the Example were both fixed at 4 μm and the line interval I was fixed at 4 μm. Further, the distance between each of the signal lines 102 and the ground layer 101 of the conventional impedance converter was 7 μm and the thickness of the signal lines 102 was 2 μm.

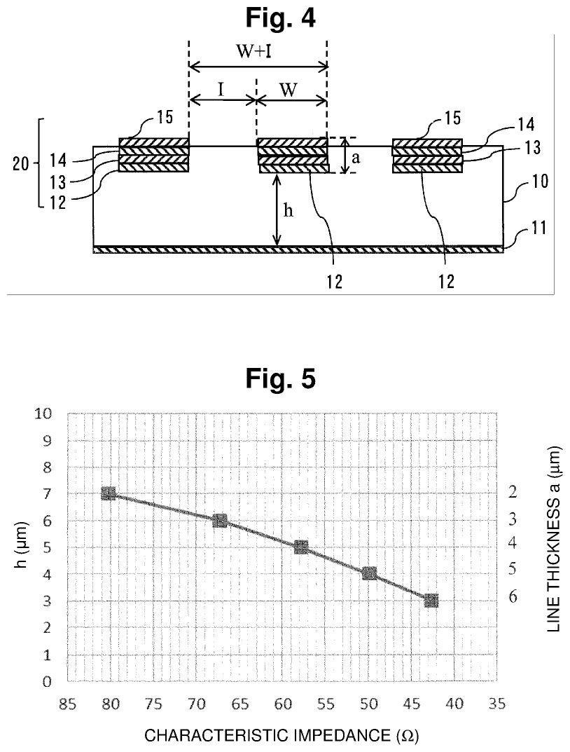

In simulation, a distance h between each of the signal lines 20 and the ground layer ii of the impedance converter of the Example is used as a parameter as shown in FIG. 4. Further, the line width W and the substantial line-to-line distance W+I are used as indexes of effects on ordinate axes in FIG. 3.

In the conventional impedance converter, an increase in the output-side line width from 4 μm to 14 μm (in the line-to-line distance W+I, from 8 μm to 18 μm) results in a decrease in the output-side characteristic impedance from 80Ω to 48Ω. In contrast, in the Example, the output-side characteristic impedance can be changed without the necessity of changing the line width or the line-to-line distance. In the example of the impedance converter of the Example of FIG. 3, when the value of the characteristic impedance is 80Ω, the distance h=7 μm and the thickness a of the signal lines 20=2 μm, and when the value of the characteristic impedance is 43Ω, the distance h=3 μm and the thickness a of the signal lines 20=6 μm.

FIG. 5 shows a relationship among the characteristic impedance Zₒ of the impedance converter of the Example, the distance h between each of the signal lines 20 and the ground layer 11, and the thickness a of the signal lines 20. It is found from FIG. 5 that a change in the distance h from 7 μm to 3 μm (in the thickness a of the signal lines 20, from 2 μm to 6 μm) results in a change in the characteristic impedance Zₒ of the impedance converter from 80Ω to 43Ω.

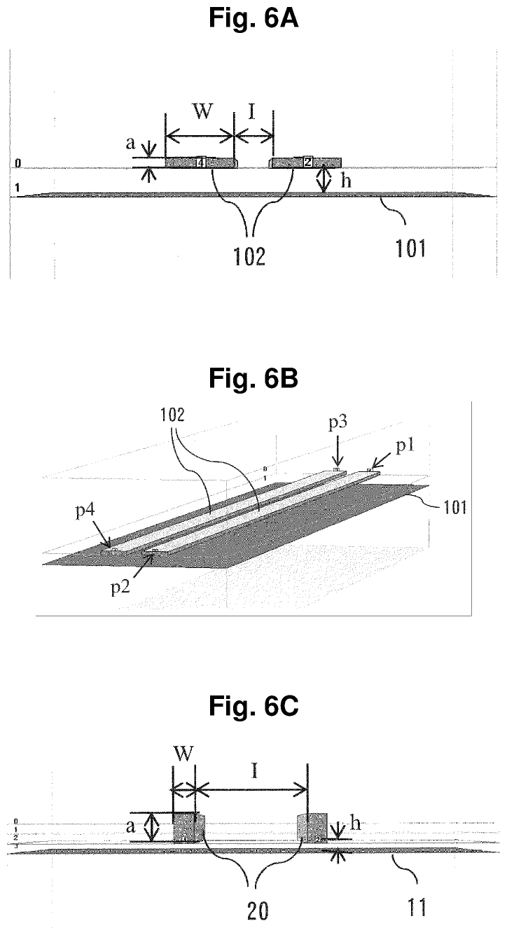

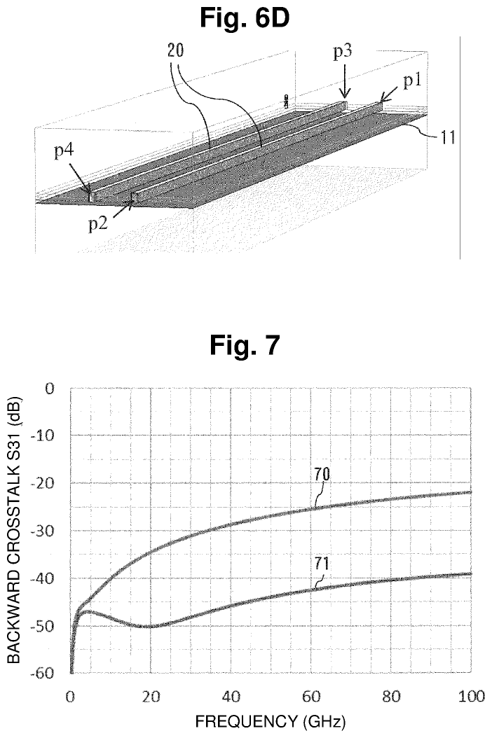

Next, a comparison is made between the conventional impedance converter and the impedance converter of the Example in terms of crosstalk amount. FIG. 6A to FIG. 6D each show a model of the microstrip line provided by an electromagnetic field simulator, Sonnet (R). FIG. 6A is a cross-sectional view of a model of the conventional impedance converter, FIG. 6B is a perspective view of the model of the conventional impedance converter, FIG. 6C is a cross-sectional view of a model of the impedance converter of the Example, and FIG. 6D is a perspective view of the model of the impedance converter of the Example.

For the purpose of comparison in crosstalk amount, the substantial line-to-line distances W+I of both the conventional example and the Example were fixed at 11.5 μm and the characteristic impedances Zₒ were uniformly set at 48.5Ω. The width W of the signal lines 102 of the conventional impedance converter shown in FIG. 6A and FIG. 6B was 7.5 μm, the thickness a of the signal lines 102 was 1 μm, the line interval I was 4 μm, and the distance h between each of the signal lines 102 and the ground layer 101 was 3 μm. Meanwhile, the width W of the signal lines 20 of the impedance converter of the Example shown in FIG. 6C and FIG. 6D was 2 μm, the thickness a of the signal lines 20 was 3 μm, the line interval I was 9.5 μm, and the distance h between each of the signal lines 20 and the ground layer 11 was 1 μm. It should be noted that the simulation has been performed with the number of the lines of the impedance converter reduced to two for the simplification of calculation.

In a case where port numbers are assigned as shown in FIG. 6B and FIG. 6D, a crosstalk amount can be directly evaluated by studying a result of an S parameter. A port p1 is an input port of one of the two signal lines 102 arranged in parallel with each other in the conventional impedance converter, a port p2 is an output port of the one of the signal lines 102, a port p3 is an input port of the other signal line 102, and a port p4 is an output of the other signal line 102. The port numbers are likewise assigned to the two signal lines 20 arranged in parallel with each other in the impedance converter of the Example.

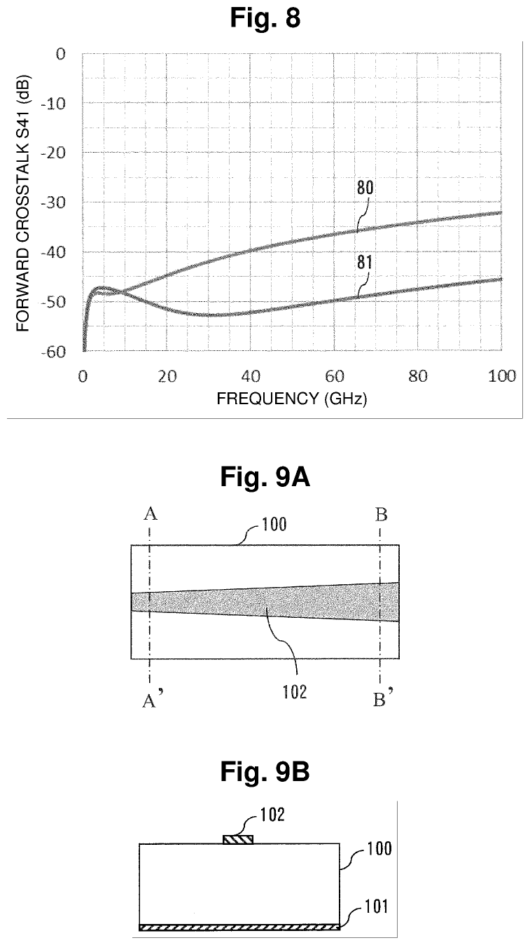

S31 is a voltage ratio between the port p1 and the port p3 resulting from application of a signal to the port p1, showing backward (near-end) crosstalk. Meanwhile, S41 is a voltage ratio between the port p1 and the port p4, showing forward (far-end) crosstalk. FIG. 7 and FIG. 8 show simulation results of S31 and S41, respectively, where a decibel scale is employed to make a difference clear.

Reference number 70 in FIG. 7 shows backward crosstalk of the conventional impedance converter and reference number 71 shows backward crosstalk of the impedance converter of the Example. Meanwhile, reference number 80 in FIG. 8 shows forward crosstalk of the conventional impedance converter and reference number 81 shows forward crosstalk of the impedance converter of the Example.

It is found from FIG. 7 that the backward crosstalk of the impedance converter of the Example is smaller than the backward crosstalk of the conventional impedance converter, in particular, in a wide range from 20 GHz to 100 GHz, smaller by 15 dB or more. Further, it is found from FIG. 8 that the forward crosstalk of the impedance converter of the Example is smaller than the forward crosstalk of the conventional impedance converter, in particular, in a wide range from 40 GHz to 100 GHz, smaller by approximately 15 dB.

As is understood from the above, the Example has a configuration in which the plurality of lines 12 to 15 are gradually stacked, whereby the distance between each of the signal lines 20 and the ground layer ii and the thickness of the signal lines 20 are gradually changed without the necessity of changing the line width or the line interval. Thus, in the Example, the distance between each of the signal lines 20 and the ground layer 11 can be gradually changed, which allows for setting a desired characteristic impedance value and providing an impedance converter in which an input-side characteristic impedance and an output-side characteristic impedance are different from each other. Further, in the Example, the signal lines 20 are brought closer to the ground layer 11, which makes it possible to reduce crosstalk noise between the lines.

Therefore, the Example allows for miniaturizing an interval between signal lines (an interval between adjacent substrate connection pads) with crosstalk noise regulated to substantially the same amount as ever. The Example allows for achieving both an improvement in line density and a reduction in crosstalk noise between lines, thus allowing for providing an impedance converter adaptable to high-density mounting.

It should be noted that the output-side characteristic impedance of the impedance converter is smaller in the Example; however, an impedance converter in which an input-side characteristic impedance is smaller may be formed. To make the input-side characteristic impedance smaller, it is only necessary to define the right end in FIG. 1A and FIG. 1B as the input side and the left side as the output side.

Further, in the Example, the number of the stacked lines is four; however, the invention is not limited thereto and it is sufficient to stack at least two lines.

Further, in the Example, the cross-sectional shape of each of the signal lines taken in the direction (the right-and-left direction in FIG. 2A to Fig. C) vertical to the signal transfer direction is a rectangle; however, the cross-sectional shape may be a trapezoid. In a case where the cross-sectional shape of each of the signal lines is a trapezoid, either a trapezoidal shape with an upper base shorter than a lower base or a trapezoidal shape with an upper base longer than a lower base is acceptable.

Further, referring to FIG. 1A, FIG. 1B, and FIG. 2A to FIG. 2C, description is made on a case where the number of the signal lines 20 arranged in parallel is three; however, the invention is not limited thereto and it goes without saying that two or four or more signal lines may be arranged in a multilane form.

### INDUSTRIAL APPLICABILITY

The Example is applicable to a technology for converting impedance in a semiconductor high-frequency module.

### REFERENCE SIGNS LIST

10 Dielectric substrate
11 Ground layer
12 to 15 Line
16, 17 Substrate connection pad
18, 19 Via
20 Signal line

1-4. (canceled)

5. An impedance converter comprising:
a dielectric substrate;
a ground layer on a rear surface of the dielectric substrate; and
a signal line in a layer from an inside to a front surface of the dielectric substrate, wherein a distance from the signal line to the ground layer gradually changes along a signal transfer direction.

6. The impedance converter according to claim 5, wherein the signal line comprises a plurality of lines stacked in the layer from the inside to the front surface of the dielectric substrate, wherein the distance from the lines to the ground layer gradually changes along the signal transfer direction.

7. The impedance converter according to claim 6, wherein the plurality of lines are stacked with first ends of the lines aligned on either a signal input side or a signal output side, wherein lengths of the lines from the first ends to second ends are different from each other.

8. The impedance converter according to claim 7, further comprising a plurality of the signal lines spaced from each other in a direction intersecting the signal transfer direction.

9. The impedance converter according to claim 5, further comprising a plurality of the signal lines spaced from each other in a direction intersecting the signal transfer direction, wherein each of the signal lines comprises a plurality of lines stacked in the layer from the inside to the front surface of the dielectric substrate, wherein the distance from the lines to the ground layer gradually changes along the signal transfer direction.

10. The impedance converter according to claim 5, further comprising substrate connection pads electrically connected to the signal line on the front surface of the dielectric substrate.

11. The impedance converter according to claim 10, further comprising vias electrically connecting respective side surfaces of the signal line and lower surfaces of the substrate connection pads.

12. A method of forming an impedance converter, the method comprising:
forming a ground layer on a rear surface of a dielectric substrate; and
forming a signal line in a layer from an inside to a front surface of the dielectric substrate, wherein a distance from the signal line to the ground layer gradually changes along a signal transfer direction.

13. The method according to claim 12, wherein forming the signal line comprises stacking a plurality of lines from the inside to the front surface of the dielectric substrate, wherein the distance from each line to the ground layer is different.

14. The method according to claim 13, wherein stacking the plurality of lines comprises stacking the lines such that first ends of the lines are aligned at either a signal input side or a signal output side, wherein lengths of the lines from the first ends to second ends are different from each other.

15. The method according to claim 14, further comprising forming a plurality of the signal lines spaced from each other in a direction intersecting the signal transfer direction.

16. The method according to claim 12, further comprising forming a plurality of the signal lines spaced from each other in a direction intersecting the signal transfer direction, wherein each of the signal lines comprises a plurality of lines stacked in the layer from the inside to the front surface of the dielectric substrate.

17. The method according to claim 12, further comprising electrically connecting substrate connection pads to the signal line on the front surface of the dielectric substrate.

18. The method according to claim 17, further comprising forming vias in the dielectric substrate, wherein the vias are electrically connected to respective side surfaces of the signal line and lower surfaces of the substrate connection pads.
